(19) United States
(12) Patent Application Publication
(10) Pub. No.: US 2026/0267382 A1
(43) Pub. Date: Sep. 10, 2026

(54) COMPUTING SYSTEM, POWER SUPPLY DEVICE, AND ELECTRICAL CONNECTION ASSEMBLY

(71) Applicant: Wistron Corporation, New Taipei City (TW)

(72) Inventors: Yu Wei LIN, New Taipei City (TW); Sheng Chia HSU, New Taipei City (TW)

(21) Appl. No.: 19/184,035

(22) Filed: Apr. 21, 2025

(30) Foreign Application Priority Data
Mar. 7, 2025 (TW) 114108602

(51) Int. Cl. G06F 1/26; H01R 4/48

(52) U.S. Cl. CPC G06F 1/26; H01R 4/48

(57) ABSTRACT

A computing system includes a computing device and a power supply device. The computing device includes a computing board and a plurality of computing elements. Each computing element has a power input portion. The power supply device includes a power supply module, a voltage regulation module, a structural member, a plurality of electrical connection assemblies, and a fixing member. The power supply module has a plurality of first power contacts. The voltage regulation module has a plurality of second power contacts. Each power input portion is coupled to each second power contact. The electrical connection assembly correspond to a perforation of the structural member. The electrical connection assembly includes an elastic conductive member accommodated in the perforation. The fixing member is configured to power contact the two ends of the elastic conductive member to a corresponding first power contact and a corresponding second power contact respectively.

### CROSS-REFERENCE TO RELATED APPLICATION

This non-provisional application claims priority under 35 U.S.C. § 119(a) to Patent Application No. 114108602 filed in Taiwan, R.O.C. on Mar. 7, 2025, the entire contents of which are hereby incorporated by reference.

### BACKGROUND

### Technical Field

The present invention relates to a computing system, and in particular, to a computing system having a power supply device and an electrical connection assembly.

### Related Art

A system on wafer (SoW) is an advanced semiconductor technology, which integrates a plurality of complete system circuits on a single wafer, to provide a higher computing capability. Although a computing system having a SoW architecture has a higher computing capability than a conventional server host board, the computing system having the SoW architecture has more computing elements than the server host board. Therefore, when a power transmission architecture is designed for the computing system having the SoW architecture, the architecture is more complex and power consuming, and generates more thermal energy.

### SUMMARY

Based on the above, in some embodiments, a computing system is provided, which includes a computing device and a power supply device. The computing device includes a computing board and a plurality of computing elements. Each computing element has a power input portion, and is arranged on the computing board. The power supply device includes a power supply module, a voltage regulation module, a structural member, a plurality of electrical connection assemblies, and a fixing member. The power supply module has a plurality of first power contacts. The voltage regulation module has a plurality of second power contacts. Each power input portion is coupled to each second power contact. The structural member is located between the power supply module and the voltage regulation module, and has a plurality of perforations. The perforations correspond to the first power contacts and the second power contacts. The electrical connection assemblies correspond to the perforations. Each electrical connection assembly includes an elastic conductive member, and is accommodated in the perforations. Two ends of each elastic conductive member are exposed from the corresponding perforation. The fixing member is configured to fix the structural member between the power supply module and the voltage regulation module, so that the two ends of the elastic conductive members are electrically connected to the corresponding first power contacts and the corresponding second power contacts respectively.

In some embodiments, a power supply device is provided, which includes a power supply module, a voltage regulation module, a structural member, a plurality of electrical connection assemblies, and a fixing member. The power supply module has a plurality of first power contacts. The voltage regulation module has a plurality of second power contacts. The structural member is located between the power supply module and the voltage regulation module, and has a plurality of perforations. The perforations correspond to the first power contacts and the second power contacts. The electrical connection assemblies correspond to the perforations. Each electrical connection assembly includes an elastic conductive member, and is accommodated in the perforations. Two ends of each elastic conductive member are exposed from the corresponding perforation. The fixing member is configured to fix the structural member between the power supply module and the voltage regulation module, so that the two ends of the elastic conductive members are electrically connected to the corresponding first power contacts and the corresponding second power contacts respectively.

In some embodiments, an electrical connection assembly is provided, which includes an elastic conductive member, a first insulating sub-member, and a second insulating sub-member. The elastic conductive member includes a first elastic sub-member and a plurality of second elastic sub-members. The first elastic sub-member has a through hole. The first insulating sub-member has a first via. The first via corresponds to the through hole. The first insulating sub-member radially covers the first elastic sub-member and two ends of the first elastic sub-member are exposed from the first insulating sub-member. The second insulating sub-member has a second via and a plurality of sub-vias. The first via is substantially coaxial with the second via. The second elastic sub-members are accommodated in the sub-vias, so that one end of the second elastic sub-member is electrically connected to the first elastic sub-member and an other end of the second elastic sub-member is exposed from the second insulating sub-member.

Based on the above, in some embodiments, when the structural member of the power supply device of the computing system is fixed to the power supply module and the voltage regulation module, the elastic conductive member can be compressed, and a power (such as a first power described later) is transmitted from the first power contact to the second power contact arranged in the voltage regulation module through the elastic conductive member. An arrangement distance between the power supply module and the voltage regulation module can be shortened by compressing the elastic conductive member, to ensure structural stability of the elastic conductive member configured to transmit the first power supply. The plurality of second elastic sub-members of each elastic conductive member may be electrically connected to the second power contact. The voltage regulation module can adjust the first power supply, output one or more second power supplies to the power input portion of the computing element, and the second power supplies may have different electrical characteristics or a same electrical characteristic. The first elastic sub-member of each elastic conductive member and the corresponding second power contact transmit the first power to the voltage regulation element. After being regulated by the voltage regulation module, the second power conforming to the corresponding computing element is outputted to a corresponding power input portion.

Various embodiments are described in detail below. However, the embodiments are merely used as examples for description, and do not limit or reduce the protection scope of the present invention. In addition, some elements are omitted in the drawings in the embodiments to clearly show the technical features of the present invention. The same reference numeral is used to indicate the same or similar elements in all the drawings.

### BRIEF DESCRIPTION OF THE DRAWINGS

FIG. 1 is a three-dimensional view of a computing system according to some embodiments of the present invention.

FIG. 2 is a schematic diagram of assembly of the computing system according to some embodiments of the present invention.

FIG. 3 is a sectional view of FIG. 1 in a direction A-A, showing that an electrical connection assembly is mounted to a perforation of a structural member.

FIG. 4 is a partial schematic diagram of a power supply device according to some embodiments of the present invention, showing only a perforation located on a side edge of a structural member and an electrical connection assembly.

FIG. 5 is a top view of FIG. 2, showing a first power contact and a second power contact in electrical contact with a single electrical connection assembly.

FIG. 6 is a schematic diagram (1) of an implementation of an electrical connection assembly according to some embodiments of the present invention.

FIG. 7 is a schematic diagram (2) of an implementation of an electrical connection assembly according to some embodiments of the present invention.

FIG. 8 is a schematic diagram (3) of an implementation of an electrical connection assembly according to some embodiments of the present invention.

FIG. 9 is a schematic diagram (4) of an implementation of an electrical connection assembly according to some embodiments of the present invention.

FIG. 10 is a sectional view of FIG. 1 in a direction of A-A, showing a partial power supply device, where a first insulating sub-member radially covers a first elastic sub-member.

FIG. 11 is a top view of a computing system according to some embodiments of the present invention, showing that a single bridging member is assembled to a structural member.

FIG. 12 is a sectional view of FIG. 11 in a direction of B-B, showing that an electrical connection assembly is mounted to a perforation of a structural member.

### DETAILED DESCRIPTION

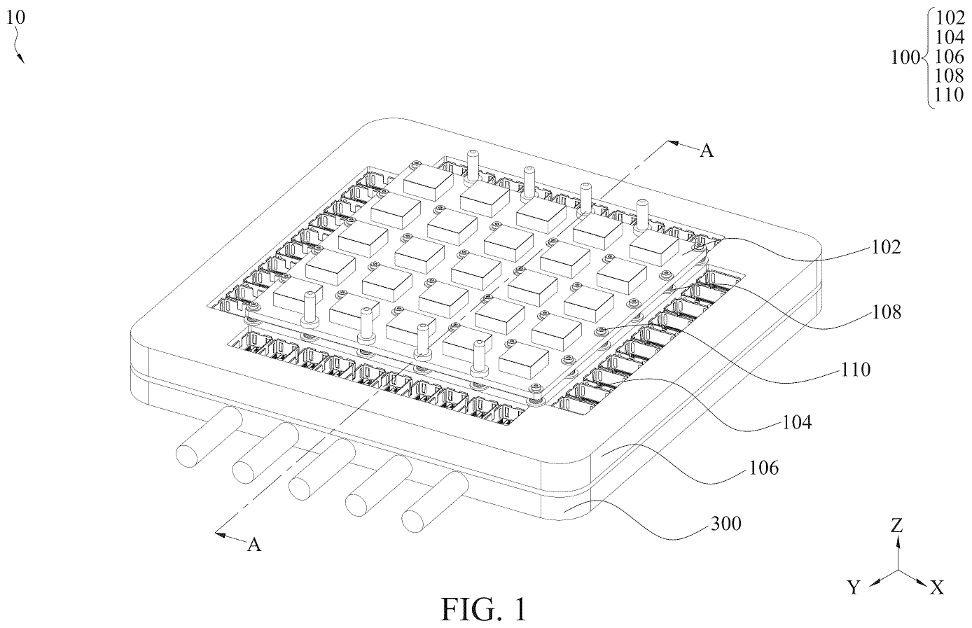

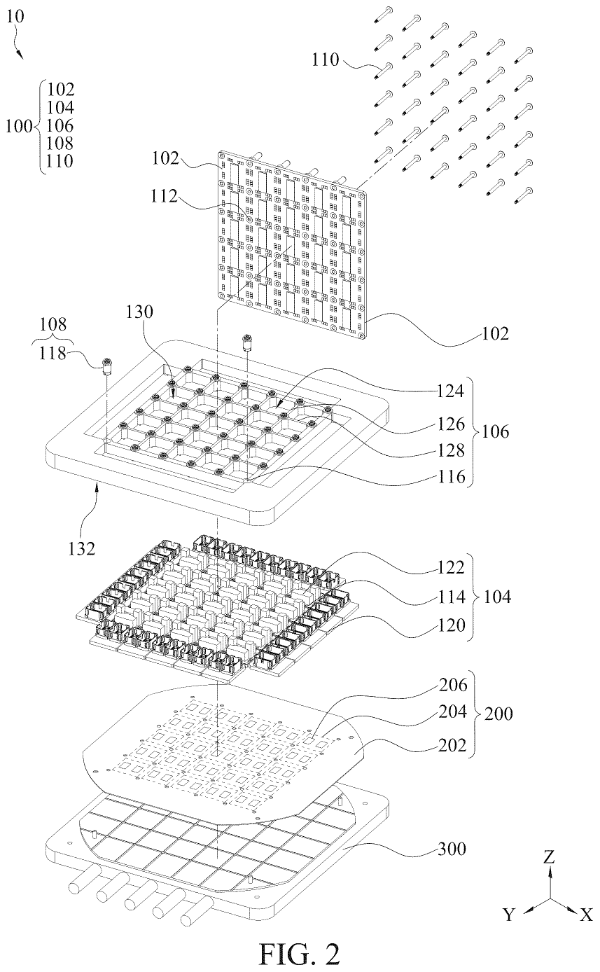

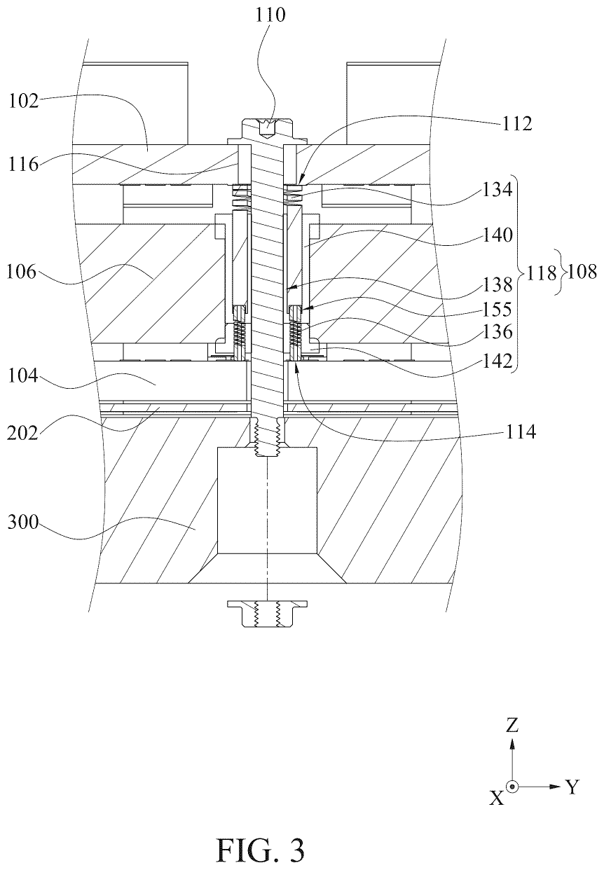

In some embodiments, as shown in FIG. 1, FIG. 2, and FIG. 3, a computing system 10 includes a power supply device 100 and a computing device 200. The power supply device 100 includes a power supply module 102, a voltage regulation module 104, a structural member 106, a plurality of electrical connection assemblies 108, and a fixing member 110. The power supply module 102 has a plurality of first power contacts 112. The voltage regulation module 104 has a plurality of second power contacts 114. The structural member 106 is located between the power supply module 102 and the voltage regulation module 104, and has a plurality of perforations 116. The perforations 116 correspond to the first power contacts 112 and the second power contacts 114. The electrical connection assemblies 108 correspond to the perforations 116. Each electrical connection assembly 108 includes an elastic conductive member 118, and is accommodated in the perforations 116. Two ends of each elastic conductive member 118 are exposed from the corresponding perforation 116. The fixing member 110 is configured to fix the structural member 106 between the power supply module 102 and the voltage regulation module 104, so that the two ends of the elastic conductive members 118 are electrically connected to the corresponding first power contacts 112 and the corresponding second power contacts 114 respectively.

The computing device 200 includes a computing board 202 and a plurality of computing elements 204. Each computing element 204 has a power input portion 206 and is arranged on the computing board 202. The computing element 204 may be a central processing unit (CPU), a graphics processing unit (GPU), an application-specific integrated circuit (ASIC), a field programmable gate array (FPGA), a tensor processing unit (TPU), or a combination of two or more of the above.

The voltage regulation module 104 is located between the computing board 202 and the structural member 106. Each power input portion 206 is respectively coupled to the second power contact 114, to receive a first power (the first power is a power before regulation) at each second power contact 114. The power input portion 206 may mean that the voltage regulation module 104 transmits a second power (the second power is a power after regulation) to an electrical contact (for example, the contact pad) of each computing element 204. The power input portion 206 may be pre-arranged at a position of the computing board 202, or may determine a position of the power input portion 206 based on an arrangement position of each computing element 204. It should be noted that each computing element 204 may have a same operating voltage or different operating voltages. Each power input portion 206 can capture the second power corresponding to a power supply specification based on the power supply specification.

It should be noted that, based on an application scenario of the computing device 200, the power supply module 102 needs to output the first power to the voltage regulation module 104, which is adjusted by the voltage regulation module 104 to the second power with one or more electrical characteristics to the computing device 200, so as to meet a power supply requirement of each computing element 204 requiring different power specifications (described in detail later).

The voltage regulation module 104 is configured to receive a first power, and adjust the first power to the second power for output to the power input portion 206 of the computing element 204. In some embodiments, the first power supply may have a single electrical characteristic. The voltage regulation module 104 can adjust the electrical characteristic (a voltage or a current) of the first power, to output a second power with a same electrical characteristic or different electrical characteristics to a corresponding power input portion 206.

The structural member 106 is configured to separate the power supply module 102 from the voltage regulation module 104 with a preset spacing. The structural member 106 fixes the power supply module 102 and the voltage regulation module 104 to the structural member 106 through the fixing member 110, so that positions thereof remain relatively fixed. When the power supply module 102 and the voltage regulation module 104 are fixed to the structural member 106, the structural member 106 can protect the power supply module 102 and the voltage regulation module 104 (described in detail later). The structural member 106 may be made of a material with good thermal conductivity, so that the voltage regulation module 104 adjusts the thermal energy generated by the second power, and can dissipate heat through the structural member 106.

In some embodiments, as shown in FIG. 2 and FIG. 3, the voltage regulation module 104 includes a substrate 120 and a plurality of voltage regulation elements 122. Each voltage regulation element 122 respectively receives the first power through one or more second power contacts 114. The voltage regulation element 122 is configured to adjust the first power to the second power, and output the second power to the corresponding power input portion 206. The voltage regulation element 122 may be, for example, a voltage regulator (VR) die. The voltage regulation elements 122 and the second power contacts 114 are located on a surface of the substrate 120 facing the structural member 106 (described in detail later). The second power contacts 114 are located outside a periphery of the voltage regulation elements 122. The structural member 106 includes a plurality of opening portions 124. At least part of the voltage regulation elements 122 is accommodated in corresponding opening portions 124. The voltage regulation module 104 is fixed to the structural member 106, and the voltage regulation element 122 is protected by the opening portions 124. In addition, the voltage regulation element 122 adjusts the thermal energy generated by the second power, and the opening portions 124 can also absorb the thermal energy to prevent the thermal energy from accumulating between the voltage regulation elements 122.

In some embodiments, as shown in FIG. 2, the perforations 116 of the structural member 106 are in one-to-one correspondence with the first power contact 112 and the second power contact 114. A quantity and positions of the perforations 116 may be set based on the power supply requirement of the computing device 200. The positions and the quantity of perforations 116 can be determined based on arrangement positions of the first power contacts 112 and the second power contacts 114. The elastic conductive member 118 may be accommodated in the perforation 116, or may be loosely fitted in the perforation 116. For example, the elastic conductive member 118 may be pressed against the perforation 116, and the elastic conductive member 118 may be fixed to the perforation 116 (described later). The elastic conductive member 118 may be loosely fitted in the perforation 116. The elastic conductive member 118 is held in the perforation 116 by an extrusion of the power supply module 102 and the voltage regulation module 104.

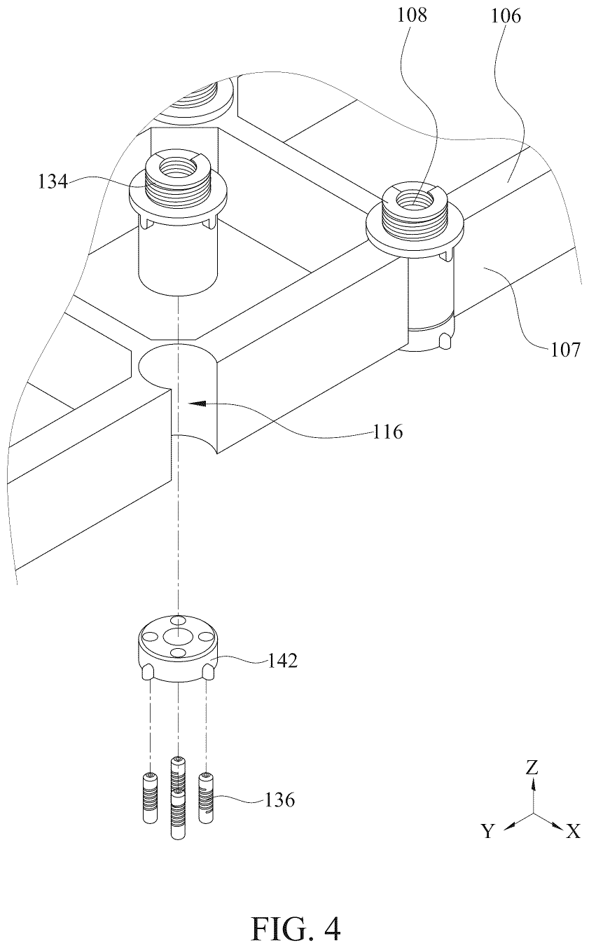

The structural member 106 has a first structural sub-member 126 and a second structural sub-member 128. The first structural sub-member 126 and the second structural sub-member 128 are arranged in a staggered manner to form a plurality of opening portions 124 on the structural member 106. In some embodiments, the perforation 116 may be provided on a point of intersection between the first structural sub-member 126 and the second structural sub-member 128. In some embodiments, as shown in FIG. 4, the perforation 116 may be provided on a side edge 106 of the structural member 107. For example, a hole that is not completely closed (such as a C-shaped hole) is provided on the side edge 107 of the structural member 106. The hole is the perforation 116 configured to accommodate the elastic conductive member 118.

In some embodiments, as shown in FIG. 2, the structural member 106 further includes a first mounting portion 130 and a second mounting portion 132. The first mounting portion 130 and the second mounting portion 132 may refer to two opposite surfaces of the first structural sub-member 126 and the second structural sub-member 128. The opening portions 124 are located between the first mounting portion 130 and the second mounting portion 132. When the power supply module 102 and the voltage regulation module 104 are respectively fixed to the structural member 106, the power supply module 102 is accommodated in the first mounting portion 130, and the voltage regulation module 104 is accommodated in the second mounting portion 132, as shown in FIG. 3. After the power supply module 102 and the voltage regulation module 104 are fixed to the structural member 106, a height (a length in a direction of a Z axis in FIG. 1) of the power supply device 100 is close to a height of the structural member 106. In addition, the first mounting portion 130 can limit the power supply module 102 in a horizontal direction (a direction of an X axis in FIG. 2), and the second mounting portion 132 can limit the voltage regulation module 104 in the horizontal direction.

The electrical connection assembly 108 is configured to transfer the first power from the first power contact 112 to the second power contact 114. As shown in FIG. 2, two ends of the elastic conductive member 118 are exposed from the perforation 116. When the power supply module 102 and the voltage regulation module 104 are fixed to the structural member 106, the two ends of the elastic conductive member 118 are extruded (as shown in FIG. 2, the elastic conductive member 118 is compressed in the direction of a Z axis), which can be compressed in a direction of the perforation 116, and remain electrically connected to the power supply module 102 and the voltage regulation module 104. In some embodiments, the two ends of the elastic conductive member 118 may be extruded into the perforation 116, or may slightly protrude from the perforation 116 or be flush with the two ends of the perforation 116. In some embodiments, a length of the elastic conductive member 118 after being extruded does not exceed a range of the first mounting portion 130 or the second mounting portion 132, so that the power supply module 102 and the voltage regulation module 104 may be as close as possible to the first mounting portion 130 or the second mounting portion 132.

In some embodiments, each electrical connection assembly 108 includes a plurality of elastic conductive members 118. The elastic conductive members 118 of each electrical connection assembly 108 are accommodated in the corresponding perforations 116 of the electrical connection assembly 108. The two ends of the elastic conductive members 118 are exposed from the corresponding perforations 116. The first power contact 112 and the second power contact 114 corresponding to the same perforation 116 may be electrically connected to one or more elastic conductive members 118 to transmit the first power.

The fixing member 110 has a clamping force when the structural member 106 is fixed between the power supply module 102 and the voltage regulation module 104. The clamping force can be used for holding the power supply module 102 and the voltage regulation module 104 close to the structural member 106, respectively. The fixing member 110 may be a combination of a screw and a nut. In some embodiments, the fixing member 110 is configured to fix (clamp) the structural member 106 between the power supply module 102 and the voltage regulation module 104, so that the two ends of the elastic conductive members 118 are electrically connected to the corresponding first power contacts 112 and the corresponding second power contacts 114 respectively. As shown in FIG. 3, the fixing member 110 can extend through the power supply module 102, the structural member 106, and the voltage regulation module 104 in sequence, so that the power supply module 102 and the voltage regulation module 104 remain relatively stationary at a position of the structural member 106. Relatively, the positions of the first power contact 112 and the second power contact 114 corresponding to each elastic conductive member 118 electrically connected thereto also remain relatively stationary. When the fixing member 110 is fixed between the power supply module 102 and the voltage regulation module 104, the fixing member 110 can limit the power supply module 102 and the voltage regulation module 104 in a horizontal direction (a direction of a Y axis in FIG. 3) and a direction of a plumb (a direction of a Z axis in FIG. 3).

In some embodiments, the power supply device 100 may output the second power to the power input portion 206 at a preset position through the voltage regulation module 104 based on a power demand of the computing device 200. Each first power contact 112 respectively transmits the first power to the corresponding second power contact 114 through the elastic conductive member 118 electrically connected thereto. The voltage regulation module 104 adjusts the first power to the second power. The computing device 200 can capture the second power that meets the electrical a characteristic requirement from the power input portion 206 at the preset position based on the power demand.

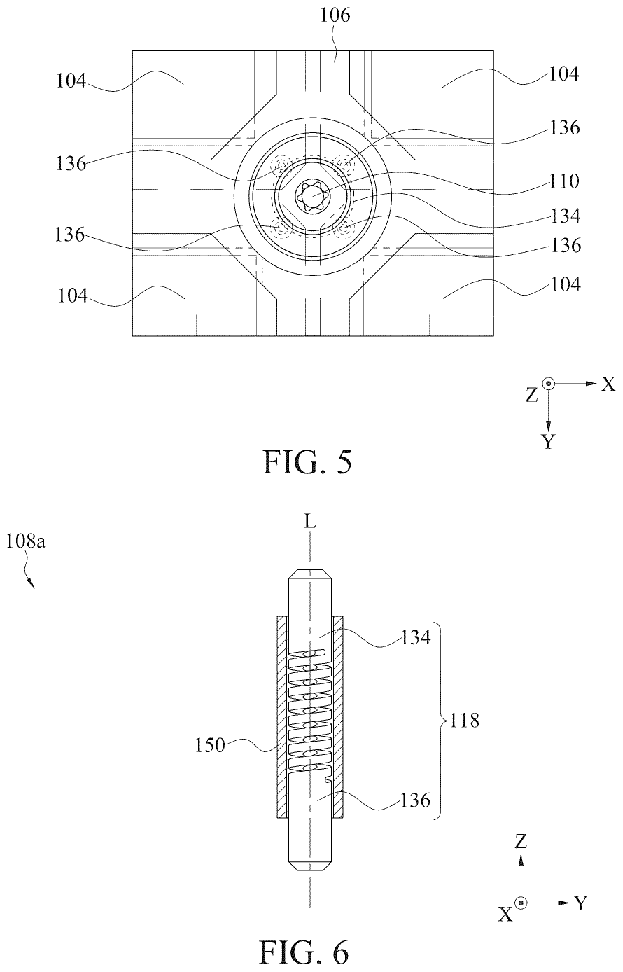

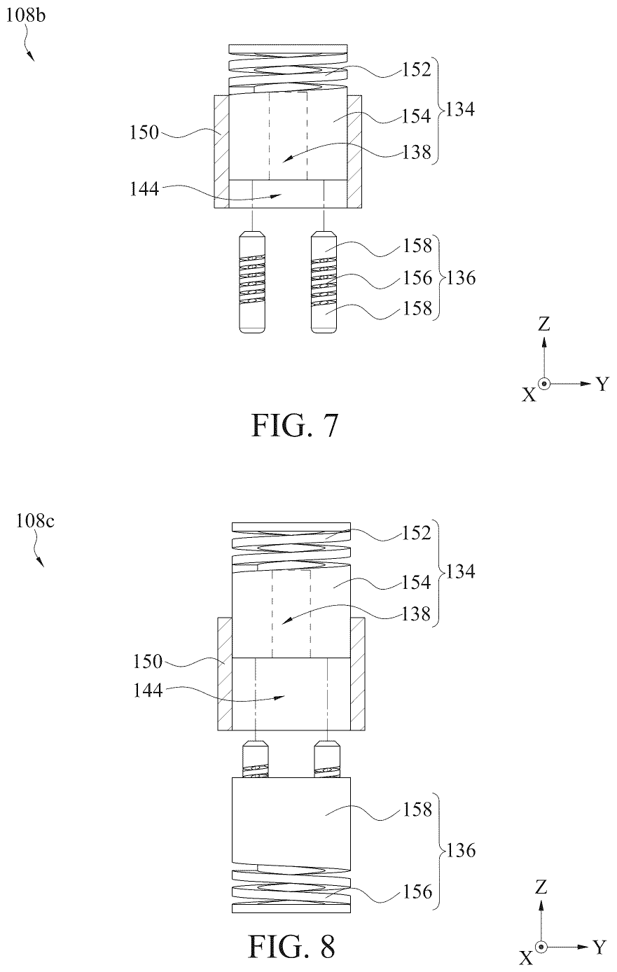

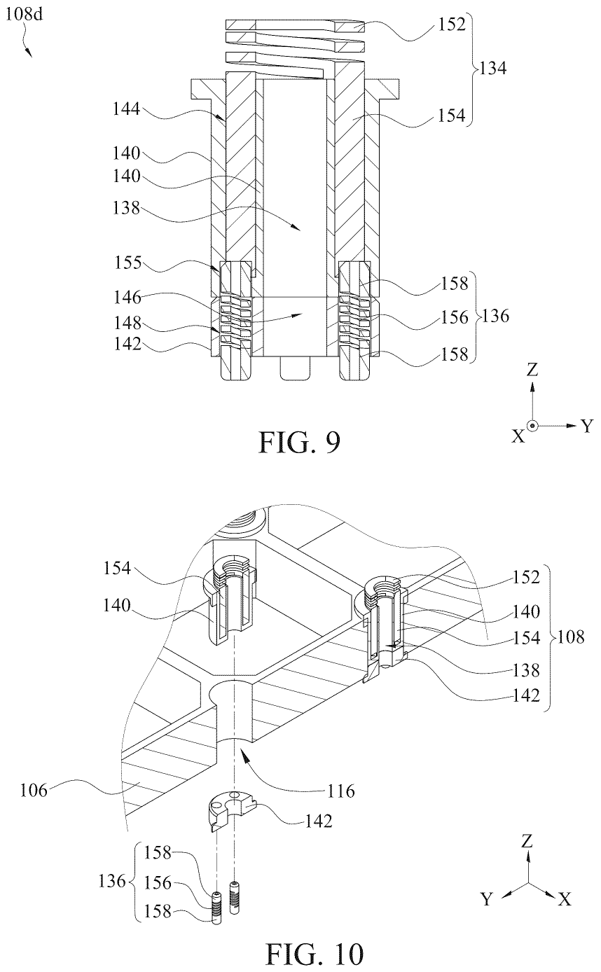

In some embodiments, as shown in FIG. 3 and FIG. 5, each elastic conductive member 118 includes a first elastic sub-member 134 and one or more second elastic sub-members 136. The first power contacts 112, the corresponding first elastic sub-members 134, the corresponding second elastic sub-members 136, and the corresponding second power contacts 114 are electrically connected in sequence through the fixing member 110. When the fixing member 110 is fixed between the power supply module 102 and the voltage regulation module 104, the first power contact 112 corresponding to the same perforation 116 can be electrically connected to one or more second power contacts 114 through the elastic conductive member 118. For example, in FIG. 3, FIG. 7, and FIG. 9, the elastic conductive member 118 has one first elastic sub-member 134 and four second elastic sub-members 136. The fixing member 110 is arranged in the elastic conductive member 118 of the perforation 116 when being fixed. One first elastic sub-member 134 corresponds to one first power contact 112 (for example, the first power contact 112 in FIG. 3). The four second elastic sub-members 136 respectively correspond to one adjacent second power contact 114 (for example, the second power contact 114 in FIG. 3). For another example, in FIG. 6 and FIG. 8, the elastic conductive member 118 has one first elastic sub-member 134 and one second elastic sub-member 136. The fixing member 110 is arranged in the elastic conductive member 118 of the perforation 116 when being fixed. One first elastic sub-member 134 corresponds to one first power contact 112. The one second elastic sub-members 136 respectively correspond to one second power contact 114.

In some embodiments, specifically, the fixing member 110 may be arranged in a part or an entirety of the perforation 116. For example, the fixing member 110 may avoid the perforation 116 corresponding to the first power contact 112 and the second power contact 114, and fix the structural member 106 between the power supply module 102 and the voltage regulation module 104. The fixing member 110 may alternatively be arranged in the perforation 116 corresponding to the first power contact 112 and the second power contact 114.

Refer to FIG. 3, FIG. 6, FIG. 7, FIG. 8, and FIG. 9. FIG. 6 to FIG. 9 are schematic diagrams of a plurality of implementations of an electrical connection assembly according to some embodiments of the present invention. An implementation of electrical connection assemblies (108a, 108b, 108c, or 108d) are described below by using examples.

Refer to FIG. 3 and FIG. 6. In some examples, for example, the electrical connection assemblies 108a shown in FIG. 6, each elastic conductive member 118 includes a first elastic sub-member 134 and a second elastic sub-member 136. The first elastic sub-member 134 and the one second elastic sub-member 136 may be connected to each other end to end. When the electrical connection assemblies 108 are respectively located in the corresponding perforations 116, the first elastic sub-member 134 and the second elastic sub-member 136 of each elastic conductive member 118 may respectively correspond to the first power contact 112 and the second power contact 114 located on a same plumb line L. When the elastic conductive member 118 is located in the perforation 116, the first power contact 112 and the second power contact 114 corresponding to the same perforation 116 can output the first power through the elastic conductive member 118. It should be noted that based on an output position of the first power, the electrical connection assembly 108a may be arranged at a part of the perforation 116 at which the first power is outputted, and the fixing member 110 may be arranged at an other part of the perforation 116.

In some examples, for example, the electrical connection assemblies (108, 108b, 108c, or 108d) shown in FIG. 3, FIG. 7, FIG. 8, and FIG. 9, each elastic conductive member 118 includes a first elastic sub-member 134 and a plurality of second elastic sub-members 136. Each first elastic sub-member 134 has a through hole 138. The fixing members 110 respectively correspond to the electrical connection assemblies (108, 108b, 108c, or 108d). The fixing members 110 respectively extend through the corresponding through holes 138 to fix the structural member 106 between the power supply module 102 and the voltage regulation module 104. In some embodiments, the second elastic sub-members 136 of the electrical connection assemblies (108, 108b, 108c, or 108d) surround the corresponding fixing member 110.

In some embodiments, for the foregoing expression “the fixing member 110 may alternatively be arranged in the perforation 116 having the first power contact 112 and the second power contact 114”, the perforation 116 may be a through hole 138 formed in the first elastic sub-member 134. In other words, during the fabrication of the structural member 106, the first elastic sub-member 134 may be pre-placed at a preset position of the structural member 106, to use the through hole 138 as the perforation 116 of the structural member 106.

In some examples, for example, the electrical connection assemblies (108 or 108d) shown in FIG. 3 and FIG. 9, each electrical connection assembly (108 or 108d) further includes a first insulating sub-member 140 and a second insulating sub-member 142. The first insulating sub-member 140 of each electrical connection assembly (108c or 108d) radially covers the corresponding first elastic sub-member 134. Each first insulating sub-member 140 has a first via 144. Each second insulating sub-member 142 has a second via 146 and a plurality of sub-vias 148. Each fixing member 110 extends through the first via 144 of the first insulating sub-member 140 and the second via 146 of the second insulating sub-member 142 of the corresponding electrical connection assembly 108. The second elastic sub-members 136 of each electrical connection assembly 108 are respectively accommodated in corresponding sub-vias 148. When the electrical connection assemblies (108 or 108d) are located in the perforation 116, the first insulating sub-member 140 and the second insulating sub-member 142 can avoid forming an electrical conduction with the perforation 116, so that the first power transmitted by the electrical connection assemblies (108c or 108d) does not affect each other (for example, a short circuit). The foregoing expression “the first insulating sub-member 140 radially covers the corresponding first elastic sub-member 134” may mean that a radially inner side and a radially outer side of the first elastic sub-member 134 are both covered by the first insulating sub-member 140 and only two ends of the first elastic sub-member 134 are exposed.

In some examples, for example, the electrical connection assemblies (108 or 108d) shown in FIG. 3 and FIG. 9, the first insulating sub-member 140 and the second insulating sub-member 142 may be made of an elastic insulating material (for example, rubber, silicone, polyurethane, or a thermoplastic elastomer (TPE)). The first elastic sub-member 134 can be elastically fixed to one end of the perforation 116 through the first insulating sub-member 140. The second elastic sub-member 136 may be fixed to an other end of the perforation 116 through the second insulating sub-member 142.

In some examples, for example, the electrical connection assemblies (108 or 108d) shown in FIG. 3 and FIG. 9, at least a part of the first elastic portion 152 is exposed from the first insulating sub-member 140. At least a part of the second elastic portion 156 is located within the second insulating sub-member 142. When the power supply module 102 is arranged on the first mounting portion 130, the first elastic portion 152 may be electrically connected to the first power contact 112. When the voltage regulation module 104 is arranged on the second mounting portion 132, a part of the second elastic portion 156 exposed from the second insulating sub-member 142 may be electrically connected to the second power contact 114.

In some embodiments, for example, the electrical connection assemblies (108a, 108b, or 108c) shown in FIG. 6, FIG. 7, and FIG. 8, each electrical connection assembly (108a, 108b, or 108c) further includes an insulating member 150. The insulating members 150 are respectively accommodated in the perforations 116, and surround the corresponding elastic conductive members 118. In some examples, for example, the electrical connection assemblies 108a or 108c shown in FIG. 6 and FIG. 8, the insulating member 150 surrounds one first elastic sub-member 134 and one second elastic sub-member 136. Therefore, the first power transmitted by each electrical connection assembly 108a does not affect each other. In some examples, for example, the electrical connection assemblies 108b shown in FIG. 7, the insulating member 150 surrounds one first elastic sub-member 134 and a plurality of second elastic sub-members 136. In some examples, if the structural member 106 is made of a conductive material, the insulating member 150 surrounds the first elastic sub-member 134 and/or the second elastic sub-member 136, which may mean that the insulating member 150 surrounds an entirety or a part of a side edge of the first elastic sub-member 134 and/or the second elastic sub-member 136. The insulating member 150 may be, for example, a hollowed-out insulating ring (for example, a C-ring or an O-ring) or a plurality of insulating pieces arranged at intervals between the first elastic sub-member 134 (or the second elastic sub-member 136) and the perforation 116.

In some examples, for example, the electrical connection assemblies (108a, 108b, or 108c) shown in FIG. 6, FIG. 7, and FIG. 8, the insulating member 150 surrounds the first elastic sub-member 134. When a part of the insulating member 150 protrudes from the first elastic sub-member 134 to allow the second elastic sub-member 136 to be located in the perforation 116, the second elastic sub-member 136 can be limited in the insulating member 150, and the first elastic sub-member 134 and the second elastic sub-member 136 are prevented from contacting the perforation 116. It should be noted that, if the structural member 106 is made of a non-insulating material, that the insulating member 150 surrounds the first elastic sub-member 134 and/or the second elastic sub-member 136 may mean that the insulating member 150 surrounds an entirety or a part of a side edge of the first elastic sub-member 134 and/or the second elastic sub-member 136. The insulating member 150 may be, for example, a hollowed-out insulating ring (for example, a C-ring or an O-ring) or a plurality of insulating pieces arranged at intervals between the first elastic sub-member 134 (or the second elastic sub-member 136) and the perforation 116.

In some examples, for example, the electrical connection assemblies (108a, 108b, or 108c) shown in FIG. 6, FIG. 7, and FIG. 8, the insulating member 150 may be made of an elastic insulating material (for example, rubber, silicone, polyurethane, or TPE). A width of the perforation 116 is less than or equal to a width of the insulating member 150. The first elastic sub-member 134 and the second elastic sub-member 136 may be elastically fixed in the perforation 116 through the insulating member 150.

In some examples, if the structural member 106 is made of an insulating material, the electrical connection assemblies (108a, 108b, or 108c) may not have the insulating member 150, and the electrical connection assemblies (108a, 108b, or 108c) are arranged in the perforation 116. When the first elastic sub-member 134 and the second elastic sub-member 136 transmit the first power, the first power contacts 112 (or the second power contacts 114) corresponding to different perforations 116 can avoid affecting each other.

In some examples, for example, the electrical connection assemblies (108, 108a, or 108d) shown in FIG. 3, FIG. 7, and FIG. 9, each first elastic sub-member 134 includes a first elastic portion 152 and a first post portion 154. The first elastic portion 152 is connected to the first post portion 154. Each second elastic sub-member 136 includes a second elastic portion 156 and two second post portions 158. Two ends of the second elastic portion 156 are respectively connected to the two second post portions 158. The first power may be sequentially transmitted to the first elastic portion 152, the first post portion 154, and one end of the second post portion 158 through the first power contact 112, and then transmitted to the corresponding one or more second power contacts 114 through an other end of the second post portion 158. In some examples, for example, the electrical connection assemblies (108 or 108d) shown in FIG. 3 and FIG. 9, the foregoing expression “the first insulating sub-member 140 radially covers the corresponding first elastic sub-member 134” may mean that a radial inner side and a radial outer side of the first post portion 154 are both covered by the first insulating sub-member 140 with only a part or an entirety of the first elastic portion 152 being exposed. When the power supply module 102 is mounted toward the structural member 106, the power supply module 102 squeezes the first elastic sub-member 134 to reduce a distance from the structural member 106.

In some examples, for example, the electrical connection assemblies 108b shown in FIG. 8, each first elastic sub-member 134 includes a first elastic portion 152 and a first post portion 154. The first elastic portion 152 is connected to the first post portion 154. Each second elastic sub-member 136 includes a second elastic portion 156 and a second post portion 158. The second elastic portion 156 is connected to the second post portion 158. The first power supply can be sequentially transmitted to the first elastic portion 152, the first post portion 154, and the second post portion 158 at the first power contact 112, and then transmitted to the corresponding one or more second power contacts 114 through the second elastic portion 156.

In some examples, for example, the electrical connection assemblies 108 shown in FIG. 10, the first elastic sub-member 134 of each electrical connection assembly 108d is embedded in the corresponding first insulating sub-member 140. For example, the first elastic sub-member 134 is covered by the corresponding first insulating sub-member 140 through insert molding. In the injection molding process of the first insulating sub-member 140, the first elastic sub-member 134 is respectively arranged at a position where the first insulating sub-member 140 is preformed (for example, pre-placed in a mold). When an operation of the injection molding is completed, the first elastic sub-member 134 can be embedded in the first insulating sub-member 140.

In some examples, as shown in FIG. 10, the first insulating sub-member 140 is matched to a corresponding second insulating sub-member 142. Specifically, the first insulating sub-member 140 is embedded in one end of the perforation 116, and the second insulating sub-member 142 is embedded in an other end of the perforation 116. The first insulating sub-member 140 and the second insulating sub-member 142 may be matched to each other through the perforation 116.

In some examples, as shown in FIG. 10, in the injection molding process of the structural member 106, the first elastic sub-member 134 and the first insulating sub-member 140 are first arranged at one end of a preformed position of the perforation 116, and the second elastic sub-member 136 and the second insulating sub-member 142 are arranged at an other end of a preformed position of the perforation 116. When the structural member 106 is completed by injection molding, the first insulating sub-member 140 and the second insulating sub-member 142 can be matched to each other through the perforation 116.

In some examples, as shown in FIG. 10, the first elastic sub-member 134 is embedded in the corresponding first insulating sub-member 140. The second elastic sub-member 136 is embedded in the corresponding second insulating sub-member 142. A width of the first insulating sub-member 140 and/or the second insulating sub-member 142 (a length of a Y axis or an X axis in FIG. 10) is greater than or equal to a width of the perforation 116. The first insulating sub-member 140 and/or the second insulating sub-member 142 can be inserted into the perforation 116 by external extrusion. In this way, the first insulating sub-member 140 and the second insulating sub-member 142 may be matched to each other through the perforation 116.

In some embodiments, as shown in FIG. 3 and FIG. 9, the first post portion 154 has at least one connecting recess 155. One end of the second elastic portion 156 may be matched to the connecting recess 155, so that the first elastic sub-member 134 is electrically connected to the second elastic sub-member 136 to transmit the first power.

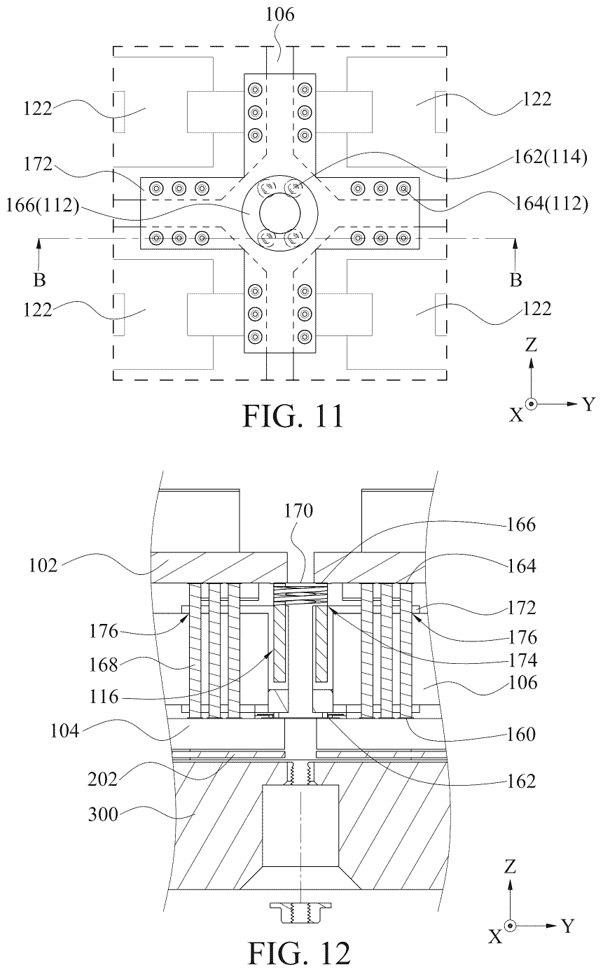

In some embodiments, as shown in FIG. 11 and FIG. 12, the second power contacts 114 located between two adjacent voltage regulation elements 122 are referred to as second adjacent contacts 160, and the other second power contacts 114 are referred to second main contacts 162. The first power contacts 112 corresponding to the second adjacent contacts 160 are referred to as first adjacent contacts 164, and the other first power contacts 112 are referred to as first main contacts 166. The electrical connection assemblies 108 corresponding to the second adjacent contacts 160 are referred to as adjacent connection assemblies 168, and the other electrical connection assemblies 108 are referred to as main connection assemblies 170.

In some embodiments, as shown in FIG. 11 and FIG. 12, the structural member 106 further includes a plurality of bridging members 172. Each bridging member 172 includes a main engagement hole 174 and a plurality of adjacent engagement holes 176. The main engagement holes 174 correspond to the first main contacts 166, the second main contacts 162, the main connection assemblies 170, and the perforations 116 of the structural member 106. The adjacent engagement hole 176 correspond to the first adjacent contacts 164, the second adjacent contacts 160, and the adjacent connection assemblies 168. The adjacent connection assemblies 168 are accommodated in the adjacent engagement holes 176, and the main connection assemblies 170 are accommodated in the main engagement holes 174. The adjacent connection assembly 168 is partially accommodated in the adjacent engagement hole 176, and two ends of the adjacent connection assembly 168 are exposed from the adjacent engagement hole 176. The first adjacent contact 164 and the first main contact 166 can receive the first power, and transmit the first power to the voltage regulation module 104 for regulating. In some examples, the power supply module 102 and the voltage regulation module 104 may transmit an electrical signal to each other through the adjacent connection assemblies 168 to provide and receive the first power, or communicate to confirm a power supply status.

In some embodiments, as shown in FIG. 1, FIG. 2, FIG. 3, and FIG. 12, the computing system 10 further includes a heat sink 300. The computing device 200 is located between the heat sink 300 and the voltage regulation module 104. The heat sink 300 is connected to the computing board 202, to dissipate heat for the computing board 202. The heat sink 300 may be a heat dissipation plate, a liquid-cooling heat dissipation device, or an air-cooling heat conducting device.

Based on the above, in some embodiments, when the structural member 106 of the power supply device 100 of the computing system 10 is fixed to the power supply module 102 and the voltage regulation module 104, the elastic conductive member 118 can be compressed, and the first power is transmitted from the first power contact 112 to the second power contact 114 through the elastic conductive member 118. An arrangement distance between the power supply module 102 and the voltage regulation module 104 can be shortened by compressing the elastic conductive member 118, to ensure structural stability of the elastic conductive member 118 configured to transmit the first power supply. The plurality of second elastic sub-members 136 of each elastic conductive member 118 may be electrically connected to the second power contact 114. The voltage regulation module 104 can adjust the first power supply, output one or more second power supplies to the power input portion 206 of the computing element 204, and the second power supplies may have different electrical characteristics or a same electrical characteristic. The first elastic sub-member 134 of each elastic conductive member 118 and the corresponding second power contact 114 transmit the first power to the voltage regulation element 122. After being regulated by the voltage regulation element 122, the second power conforming to the corresponding computing element 204 is outputted.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A power supply device, comprising:
a power supply module, having a plurality of first power contacts;
a voltage regulation module, having a plurality of second power contacts;
a structural member, located between the power supply module and the voltage regulation module and having a plurality of perforations, wherein the perforations correspond to the first power contacts and the second power contacts;
a plurality of electrical connection assemblies, corresponding to the perforations, wherein each electrical connection assembly comprises an elastic conductive member, the elastic conductive members are respectively accommodated in the perforations, and two ends of each elastic conductive member are exposed from the corresponding perforation; and
a fixing member, configured to fix the structural member between the power supply module and the voltage regulation module, so that the two ends of the elastic conductive members are electrically connected to the corresponding first power contacts and the corresponding second power contacts respectively.

2. The power supply device according to claim 1, wherein each elastic conductive member comprises a first elastic sub-member and a plurality of second elastic sub-members, and each first power contact, the corresponding first elastic sub-member, the corresponding second elastic sub-members, and the corresponding second power contacts are electrically connected in sequence through the fixing member.

3. The power supply device according to claim 2, wherein each first elastic sub-member has a through hole, the fixing members correspond to the electrical connection assemblies, the fixing members respectively extend through the corresponding through holes to fix the structural member between the power supply module and the voltage regulation module, and the second elastic sub-members of each electrical connection assembly surround the corresponding fixing member.

4. The power supply device according to claim 3, wherein each electrical connection assembly further comprises a first insulating sub-member and a second insulating sub-member, the first insulating sub-member of each electrical connection assembly radially covers the corresponding first elastic sub-member, each first insulating sub-member has a first via, each second insulating sub-member has a second via and a plurality of sub-vias, each fixing member extends through the first via of the first insulating sub-member and the second via of the second insulating sub-member of the corresponding electrical connection assembly, and the second elastic sub-members of each electrical connection assembly are respectively accommodated in the corresponding sub-vias.

5. The power supply device according to claim 4, wherein each first elastic sub-member comprises a first elastic portion and a first post portion, the first elastic portion is connected to the first post portion, at least part of the first elastic portion is exposed from the first insulating sub-member, each second elastic sub-member comprises a second elastic portion and two second post portions, two ends of the second elastic portion are respectively connected to the two second post portions, and at least part of the second elastic portion is located in the second insulating sub-member.

6. The power supply device according to claim 4, wherein the first elastic sub-member of each electrical connection assembly is embedded in the corresponding first insulating sub-member.

7. The power supply device according to claim 1, wherein each elastic conductive member has a through hole, and the fixing members respectively extend through the corresponding through holes to fix the structural member between the power supply module and the voltage regulation module.

8. The power supply device according to claim 7, wherein each electrical connection assembly further comprises an insulating member, and the insulating members are respectively located and accommodated in the perforations and surround the corresponding elastic conductive members.

9. The power supply device according to claim 1, wherein each elastic conductive member comprises a first elastic sub-member and a second elastic sub-member, and each first power contact, the corresponding first elastic sub-member, the corresponding second elastic sub-members, and the corresponding second power contacts are electrically connected in sequence through the fixing member.

10. The power supply device according to claim 1, wherein the voltage regulation module comprises a substrate and a plurality of voltage regulation elements, the voltage regulation elements and the second power contacts are located on a surface of the substrate facing the structural member, the structural member comprises a plurality of opening portions, and at least part of the voltage regulation elements is accommodated in the corresponding opening portions.

11. The power supply device according to claim 10, wherein the second power contacts located between two adjacent voltage regulation elements are referred to as second adjacent contacts, the other second power contacts are referred to second main contacts, the first power contacts corresponding to the second adjacent contacts are referred to as first adjacent contacts, the other first power contacts are referred to as first main contacts, the electrical connection assemblies corresponding to the second adjacent contacts are referred to as adjacent connection assemblies, the other electrical connection assemblies are referred to as main connection assemblies, the structural member further comprises a plurality of bridging members, each bridging member comprises a main engagement hole and a plurality of adjacent engagement holes, the main engagement holes correspond to the first main contacts, the second main contacts, the main connection assemblies, and the perforations of the structural member, and the adjacent engagement holes correspond to the first adjacent contacts, the second adjacent contacts, and the adjacent connection assemblies, the adjacent connection assemblies are accommodated in the adjacent engagement holes, and the main connection assemblies are accommodated in the main engagement holes.

12. A computing system, comprising:
a computing device, comprising a computing board and a plurality of computing elements, wherein each computing element is arranged on the computing board to have at least one power input portion; and
a power supply device, comprising:
a power supply module, having a plurality of first power contacts;
a voltage regulation module, having a plurality of second power contacts, wherein the least one power input portion is respectively coupled to the second power contacts;
a structural member, located between the power supply module and the voltage regulation module and having a plurality of perforations, wherein the perforations correspond to the first power contacts and the second power contacts;
a plurality of electrical connection assemblies, corresponding to the perforations, wherein each electrical connection assembly comprises an elastic conductive member, the elastic conductive members are respectively accommodated in the perforations, and two ends of each elastic conductive member are exposed from the corresponding perforation; and
a fixing member, configured to fix the structural member between the power supply module and the voltage regulation module, so that the two ends of the elastic conductive members are electrically connected to the corresponding first power contacts and the corresponding second power contacts respectively.

13. The computing system according to claim 12, wherein each elastic conductive member comprises a first elastic sub-member and a plurality of second elastic sub-members, and the first power contacts, the corresponding first elastic sub-members, the corresponding second elastic sub-members, and the corresponding second power contacts are electrically connected in sequence.

14. The computing system according to claim 13, wherein each first elastic sub-member has a through hole, the fixing members correspond to the electrical connection assemblies, the fixing members respectively extend through the corresponding through holes to fix the structural member between the power supply module and the voltage regulation module, and the second elastic sub-members of each electrical connection assembly surround the corresponding fixing member.

15. The computing system according to claim 14, wherein each electrical connection assembly further comprises a first insulating sub-member and a second insulating sub-member, the first insulating sub-member of each electrical connection assembly radially covers the corresponding first elastic sub-member, each first insulating sub-member has a first via, each second insulating sub-member has a second via and a plurality of sub-vias, each fixing member extends through the first via of the first insulating sub-member and the second via of the second insulating sub-member of the corresponding electrical connection assembly, and the second elastic sub-members of each electrical connection assembly are respectively accommodated in the corresponding sub-vias.

16. The computing system according to claim 15, wherein each first elastic sub-member comprises a first elastic portion and a first post portion, the first elastic portion is connected to the first post portion, at least part of the first elastic portion is exposed from the first insulating sub-member, each second elastic sub-member comprises a second elastic portion and two second post portions, two ends of the second elastic portion are respectively connected to the two second post portions, and at least part of the second elastic portion is located in the second insulating sub-member.

17. The computing system according to claim 12, wherein each elastic conductive member has a through hole, and the fixing members respectively extend through the corresponding through holes to fix the structural member between the power supply module and the voltage regulation module.

18. The computing system according to claim 12, wherein each elastic conductive member comprises a first elastic sub-member and a second elastic sub-member, and the first power contacts, the corresponding first elastic sub-members, the corresponding second elastic sub-members, and the corresponding second power contacts are electrically connected in sequence through the fixing members.

19. An electrical connection assembly, comprising:
an elastic conductive member, comprising a first elastic sub-member and at least one second elastic sub-member, wherein the at least one first elastic sub-member has a through hole;
a first insulating sub-member, having a first via, wherein the first via corresponds to the through hole, the first insulating sub-member radially covers the first elastic sub-member, and two ends of the first elastic sub-member are exposed from the first insulating sub-member; and
a second insulating sub-member, having a second via and a plurality of sub-vias, wherein the first via is substantially coaxial with the second via, and the at least one second elastic sub-member is accommodated in the sub-vias, so that one end of the at least one second elastic sub-member is electrically connected to the first elastic sub-member, and an other end of the at least one second elastic sub-member is exposed from the second insulating sub-member.

20. The electrical connection assembly according to claim 19, wherein each first elastic sub-member comprises a first elastic portion and a first post portion, the first elastic portion is connected to the first post portion, at least part of the first elastic portion is exposed from the first insulating sub-member, each second elastic sub-member comprises a second elastic portion and two second post portions, two ends of the second elastic portion are respectively connected to the two second post portions, and at least part of the second elastic portion is located in the second insulating sub-member.
